(19) United States
(12) Patent Application Publication
(10) Pub. No.: US 2025/0210312 A1
(43) Pub. Date: Jun. 26, 2025

(54) SUBSTRATE PROCESSING APPARATUS

(71) Applicant: SEMES CO., LTD., Cheonan-si (KR)

(72) Inventors: Sun Wook JUNG, Cheonan-si (KR); Yoon Seok CHOI, Cheonan-si (KR); Chan Young CHOI, Cheonan-si (KR); Sung Suk WI, Cheonan-si (KR); Hyung Bin IM, Cheonan-si (KR)

(73) Assignee: SEMES CO., LTD., Cheonan-si (KR)

(21) Appl. No.: 19/002,381

(22) Filed: Dec. 26, 2024

(30) Foreign Application Priority Data
Dec. 26, 2023 (KR) 10-2023-0191825

(51) Int. Cl. H01J 37/32

(52) U.S. Cl. CPC H01J 37/3222; H01J 37/32266

(57) ABSTRACT

Proposed is a substrate processing apparatus. The substrate processing apparatus includes a chamber having a processing space therein, a substrate supporting unit disposed in the processing space and configured to support a substrate, and a microwave unit for supplying microwaves to the processing space. The microwave unit is formed along a circumference of the chamber, and is configured to directly radiate microwaves to the processing space of the chamber and to the substrate.

### CROSS REFERENCE TO RELATED APPLICATION

The present application claims priority to Korean Patent Application No. 10-2023-0191825, filed Dec. 26, 2023, the entire contents of which are incorporated herein for all purposes by this reference.

### BACKGROUND OF THE INVENTION

### Field of the Invention

The present disclosure relates to a substrate processing apparatus. More particularly, the present disclosure relates to a substrate processing apparatus having a microwave unit formed along a circumference of a chamber so as to efficiently process a substrate.

### Description of the Related Art

Generally, a process for manufacturing a semiconductor device includes a deposition process for forming a film on a semiconductor substrate, a chemical/mechanical polishing process for planarizing the film, a photoresist process for forming a photoresist pattern on the film, an etching process for forming the film into a pattern having electrical characteristics by using the photoresist pattern, an ion implantation process for implanting specific ions into a predetermined region of the substrate, a cleaning process for removing impurities on the substrate, an inspection process for inspecting a surface of the substrate on which the film or the pattern is formed, and so on.

Microwaves may be used for performing various processes as described above. Plasma may be generated in an internal space of a chamber by using microwaves, or a substrate may be rapidly heated by using microwaves.

FIG. 1 is a view illustrating a conventional substrate processing apparatus.

Referring to FIG. 1, in a conventional substrate processing apparatus 1, a microwave unit 500 is formed on an upper portion of a chamber 100, and microwaves are supplied to a processing space inside the chamber 100 by using the microwave unit 500. However, when a substrate W is heated or plasma is formed by using the microwave unit 500, a distance between the substrate W and the microwave unit 500 is far, so that the substrate W heating efficiency and the plasma generation efficiency are reduced. As a result, problems such as the substrate W not being uniformly heated, plasma not being uniformly generated inside the chamber 100, and so on occur.

### SUMMARY OF THE INVENTION

Accordingly, the present disclosure has been made keeping in mind the above problems occurring in the related art, and an objective of the present disclosure is to provide a substrate processing apparatus for efficiently processing a substrate.

The technical problems that are intended to be addressed in the present disclosure are not restricted to the above described problems, and other problems, which are not mentioned herein, could be clearly understood by those of ordinary skill in the art from details described below.

According to an aspect of the present disclosure, there is provided a substrate processing apparatus including: a chamber having a processing space therein; a substrate supporting unit disposed in the processing space and configured to support a substrate; and a microwave unit for supplying microwaves to the processing space, wherein the microwave unit is formed along a circumference of the chamber, and is configured to directly radiate microwaves to the processing space of the chamber and to the substrate.

According to an aspect of the present disclosure, the microwave unit may include: a power source for generating microwaves; a waveguide for transmitting microwaves; and an antenna for transmitting microwaves, the antenna being formed in a doughnut shape.

According to an aspect of the present disclosure, a plurality of output slots may be formed in an inner circumference of the antenna.

According to an aspect of the present disclosure, the plurality of output slots may be disposed to be spaced apart from each other by a predetermined distance along the inner circumference of the antenna.

According to an aspect of the present disclosure, the plurality of output slots may be disposed as a plurality of layers partitioned in a vertical direction along the inner circumference of the antenna.

According to an aspect of the present disclosure, the plurality of output slots may have an angle of 90° to 180° with respect to a direction parallel to a surface of the substrate.

According to an aspect of the present disclosure, the chamber may be formed of quartz.

According to an aspect of the present disclosure, a side wall forming the chamber may include a region recessed toward the processing space from the side wall, and the microwave unit may be disposed in the region that is recessed.

According to an aspect of the present disclosure, the substrate processing apparatus may further include a microwave unit driving unit for driving the microwave unit up and down.

According to another aspect of the present disclosure, there is provided a substrate processing apparatus including: a chamber having a processing space therein; a substrate supporting unit disposed in the processing space and configured to support a substrate; a gas supply unit for supplying a gas to the processing space; a plasma generation unit for ionizing the supplied gas into plasma; a microwave unit for supplying microwaves to the processing space; and a control unit for controlling the gas supply unit and the plasma generation unit, wherein the microwave unit is formed along a circumference of the chamber, and is configured to heat the substrate by directly radiating microwaves to the substrate.

According to another aspect of the present disclosure, the microwave unit may include: a power source for generating microwaves; a waveguide for transmitting microwaves; and an antenna for transmitting microwaves, the antenna being formed in a doughnut shape.

According to another aspect of the present disclosure, a plurality of output slots may be formed in an inner circumference of the antenna.

According to another aspect of the present disclosure, the plurality of output slots may be disposed to be spaced apart from each other by a predetermined distance along the inner circumference of the antenna.

According to another aspect of the present disclosure, the substrate processing apparatus may further include a microwave unit driving unit for driving the microwave unit up and down.

According to still another aspect of the present disclosure, there is provided a substrate processing apparatus including: a chamber having a processing space therein; a substrate supporting unit disposed in the processing space and configured to support a substrate; a gas supply unit for supplying a gas to the processing space; a microwave unit for supplying microwaves to the processing space; and a control unit for controlling the gas supply unit and the microwave unit, wherein the microwave unit is formed along a circumference of the chamber, and is configured to ionize the supplied gas into plasma by directly radiating microwaves to the processing space of the chamber.

According to still another aspect of the present disclosure, the microwave unit may include: a power source for generating microwaves; a waveguide for transmitting microwaves; and an antenna for transmitting microwaves, the antenna being formed in a doughnut shape.

According to still another aspect of the present disclosure, a plurality of output slots may be formed in an inner circumference of the antenna.

According to still another aspect of the present disclosure, the plurality of output slots may be disposed to be spaced apart from each other by a predetermined distance along the inner circumference of the antenna.

According to still another aspect of the present disclosure, the substrate processing apparatus may further include a microwave unit driving unit for driving the microwave unit up and down.

According to still another aspect of the present disclosure, the microwave unit may be configured to be driven vertically between the gas supply unit and the substrate supporting unit by the microwave unit driving unit.

According to the present disclosure, since the microwave unit is disposed along the circumference of the chamber, microwaves may be directly supplied to the substrate and near the substrate.

In addition, since microwaves are directly supplied to the substrate, the temperature uniformity of the substrate may be increased.

In addition, since microwaves are directly supplied to a portion near the substrate, the efficiency of applying plasma to the substrate may be increased.

The effects of the present disclosure are not limited to the above-mentioned effects, and the other unmentioned effects will become apparent to those skilled in the art from the following description and drawings.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view illustrating a conventional substrate processing apparatus;

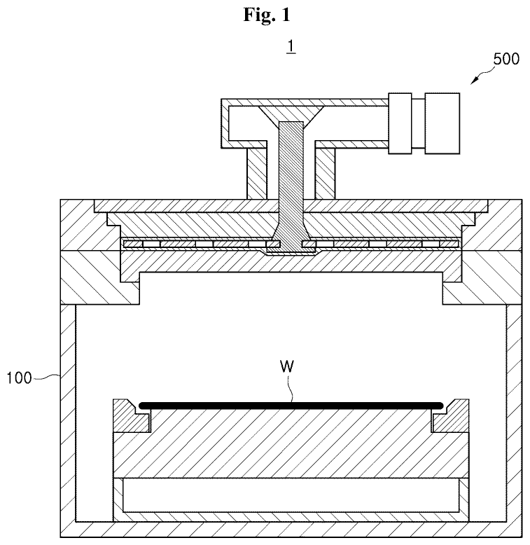

FIG. 2 is a view illustrating a substrate processing apparatus according to an embodiment of the present disclosure;

FIG. 3 is a perspective view illustrating a microwave unit formed on a circumference of a chamber according to an embodiment of the present disclosure;

FIG. 4 is a view illustrating an antenna according to an embodiment of the present disclosure;

FIG. 5 is a graph showing an average temperature of a substrate according to an embodiment of the present disclosure;

FIG. 6 is a view illustrating the antenna according to another embodiment of the present disclosure;

FIG. 7 is a view illustrating the substrate processing apparatus according to another embodiment of the present disclosure; and

FIG. 8 is a view illustrating the chamber according to another embodiment of the present disclosure.

### DETAILED DESCRIPTION OF THE INVENTION

Hereinbelow, an embodiment of the present disclosure will be described in detail with reference to the accompanying drawings such that the present disclosure can be easily embodied by one of ordinary skill in the art to which the present disclosure belongs. However, the present disclosure is not limited to the embodiment described herein and may be embodied in many different forms.

In describing the embodiment of the present disclosure, a detailed description of known function or configuration related to the present disclosure will be omitted when it may obscure the subject matter of the present disclosure, and the same reference numerals will be used throughout the drawings to refer to the elements or parts with same or similar function or operation.

Furthermore, technical terms, as will be mentioned hereinafter, are terms defined in consideration of their function in the present disclosure, which may be changed according to the intention of a user, practice, or the like. Therefore, the terms should be defined on the basis of the contents of this specification.

As used herein, the singular forms are intended to include the plural forms as well, unless the context clearly indicates otherwise. Unless the context clearly indicates otherwise, it will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof.

In the drawings, the shapes and sizes of parts and thicknesses of lines may be exaggerated for convenience of understanding.

Hereinafter, embodiments of the present disclosure will be described in detail with reference to the accompanying drawings, and in the description with reference to the accompanying drawings, like reference numerals indicate like or corresponding elements and redundant descriptions are omitted herein.

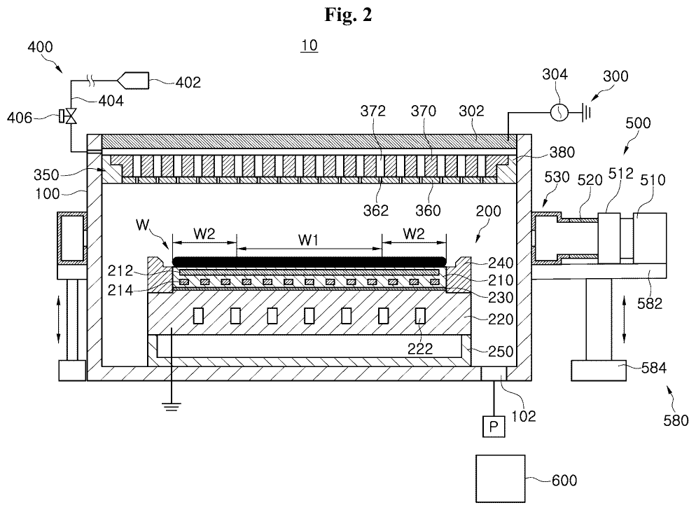

FIG. 2 is a view illustrating a substrate processing apparatus according to an embodiment of the present disclosure.

A substrate processing apparatus 10 may include a chamber 100, a substrate supporting unit 200, a plasma generation unit 300, a gas supply unit 400, a microwave unit 500, and a control unit 600.

The chamber 100 has a processing space in which a plasma processing process is performed. The chamber 100 may be formed in quartz so as to penetrate microwave supplied from the microwave unit 500 that will be described later.

An exhaust port 102 may be formed on a lower portion of the chamber 100. The exhaust port 102 may be connected to an exhaust line in which a pump P is mounted. In the exhaust port 102, reaction by-products generated during a processing process and a gas remaining inside the chamber 100 may be discharged to the outside through an exhaust line. In this situation, a space inside the chamber 100 may be depressurized with a predetermined pressure.

The substrate supporting unit 200 may be disposed on a lower region inside the chamber 100. The substrate supporting unit 200 may support a substrate W by an electrostatic force. However, the present embodiment is not limited thereto, and the substrate W may be supported in various manners such as mechanical clamping, vacuum, and so on.

When the substrate supporting unit 200 supports the substrate W by using an electrostatic force, the substrate supporting unit 200 may include an electrostatic chuck 210 and a base plate 220 supporting the electrostatic chuck 210. The electrostatic chuck 210 and the base plate 220 may be bonded with each other by a bonding layer 230. The bonding layer 230 may be formed of silicon and so on.

The electrostatic chuck 210 may be formed of a dielectric plate such as alumina, and an inner portion of the electrostatic chuck 210 may be provided with a chuck electrode 212 for generating an electrostatic force. When a voltage is applied to the chuck electrode 212 by a power source that is not illustrated, the electrostatic force is generated, and the substrate W may be adsorbed and fixed to the electrostatic chuck 210. The electrostatic chuck 210 may be provided with a heater 214 for heating the substrate W to a predetermined temperature.

The base plate 220 is positioned below the electrostatic chuck 210, and may be formed of a metal material such as aluminum. A refrigerant flow path 222 in which a cooling fluid flows is formed inside the base plate 111, so that the base plate 111 may serve as a cooling mechanism for cooling the electrostatic chuck 210. The refrigerant flow path 222 may be provided as a circulation passage through which the cooling fluid is circulated.

The substrate supporting unit 200 may include a ring member 240 surrounding the electrostatic chuck 210. The ring member 240 may serve to concentrate plasma to a region where the substrate W is positioned, and may serve to uniformly distribute the plasma density to the entire region including the substrate W edge region.

A support member 250 for supporting the electrostatic chuck 210 and the base plate 220 may be provided below the base plate 220. The support member 250 is formed in a cylindrical shape having a predetermined height, and may have a space therein.

The plasma generation unit 300 may generate plasma in the processing space inside the chamber 100. Plasma may be formed in an upper region of the substrate supporting unit 200 within the chamber 100. According to an embodiment of the present disclosure, the plasma generation unit 300 may generate plasma in the processing space inside the chamber 100 by using a Capacitively Coupled Plasma (CCP) source.

However, the present embodiment is not limited thereto. The plasma generation unit 300 is capable of generating plasma in the processing space inside the chamber 100 by using a plasma source in another manner such as an Inductively Coupled Plasma (ICP) source and so on.

The plasma generation unit 300 may include an upper electrode 302 and a high frequency power source 304. The plasma generation unit 300 may be disposed on an upper portion of a shower head unit 350. In order to generate a potential difference between the upper electrode 302 and a lower electrode, the high frequency power source 304 may generate high frequency waves on any one of the upper electrode 302 and the lower electrode. The high frequency power source 304 is connected to the upper electrode 302, and the lower electrode may be grounded. According to an embodiment of the present disclosure, the lower electrode may be the substrate supporting unit 200.

The shower head unit 350 may disperse a gas supplied from the upper portion of the shower head unit 350. In addition, the shower head unit 350 may be configured such that a gas supplied from the gas supply unit 400 is uniformly supplied to the processing space. The shower head unit 350 may include a shower head 360 and a gas injection plate 370.

The shower head 360 may be disposed below the gas injection plate 370. The shower head 360 is positioned such that the shower head 360 is spaced apart downward from an upper surface of the chamber 100 by a predetermined distance. The shower head 360 is positioned above the substrate supporting unit 200. The shower head 360 may be provided in a plate shape having a uniform thickness. A bottom surface of the shower head 360 may be anodized so as to prevent an arc generation due to plasma. A plurality of gas supply holes 362 is formed in the shower head 360. The gas supply hole 362 may be formed by penetrating upper and lower surfaces of the shower head 360 in a vertical direction.

The gas injection plate 370 is disposed above the shower head 360. The gas injection plate 370 may diffuse a gas supplied from an upper portion of the gas injection plate. A gas introduction hole 372 may be formed in the gas injection plate 370. The gas introduction hole 372 may be formed in a position corresponding to the gas supply hole 362. The gas introduction hole 372 may be in communication with the gas supply hole 362. A gas supplied from the upper portion of the shower head unit 350 may be supplied to the lower portion of the shower head 360 by sequentially passing through the gas introduction hole 372 and the gas supply hole 362. The gas injection plate 370 may include a metal material.

An insulation ring 380 may be disposed such that the insulation ring 380 surrounds the shower head 360 and the gas injection plate 370. The insulation ring 380 may be provided in an annular ring shape. The insulation ring 380 may be formed of a non-metallic material.

The gas supply unit 400 may supply a gas to the chamber 100, the gas being required for a process. Such a gas supply unit 400 may include a gas supply source 402, a gas supply line 404, and a gas injection nozzle (not illustrated). The gas supply line 404 may connect the gas supply source 402 and the gas injection nozzle (not illustrated) to each other. The gas supply line 404 may supply a gas stored in the gas supply source 402 to the gas supply nozzle. A gas supply valve 406 configured to open or close a passage of the gas supply line 404 or to adjust a flow rate of a fluid that flows along the passage may be mounted on the gas supply line 604.

Although only one gas supply source 402, one gas supply line 404, and one gas supply valve 406 are illustrated in FIG. 2, the gas supply source of the present disclosure may include a plurality of gas supply sources so as to supply a plurality of gases to the chamber 100 and may include a plurality of gas supply valves so as to independently control the supply of each of the gases.

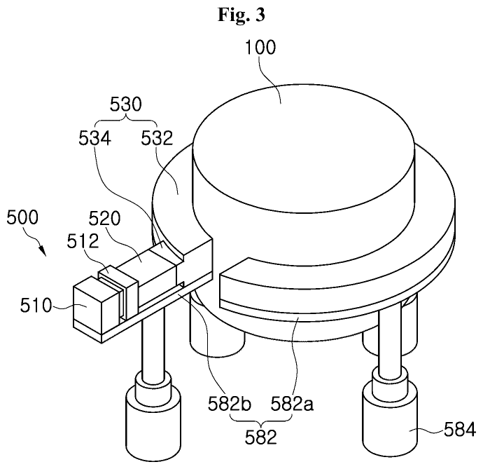

FIG. 3 is a view illustrating the microwave unit formed on a circumference of the chamber according to an embodiment of the present disclosure.

Referring to FIG. 3, the microwave unit 500 according to an embodiment of the present disclosure may be provided along the circumference of the chamber 100. The microwave unit 500 according to an embodiment of the present disclosure may include a power source 510, a waveguide 520, and an antenna 530. Furthermore, microwaves supplied from the microwave unit 500 may be directly radiated to the substrate W through the chamber 100 formed of quartz.

The power source 510 may include a matching network 512. The power source 510 is configured to generate microwaves, and the generated microwaves may have a frequency of approximately 2.3 GHZ to 2.5 GHZ. The power source 510 may be connected to the waveguide 520, and the matching network 512 may be provided between the power source 510 and the waveguide 520. The matching network 512 may match microwaves supplied through the power source 510 to a predetermined frequency.

The waveguide 520 may be provided in a tubular shape having a polygonal cross-section or a circular cross-section. An inner surface of the waveguide 520 may be provided as a conductor. As an example, the inner surface of the waveguide 520 may be formed of gold or silver. The waveguide 520 may provide a passage through which microwaves generated from the power source 510 are transmitted, and may be connected to the antenna 530.

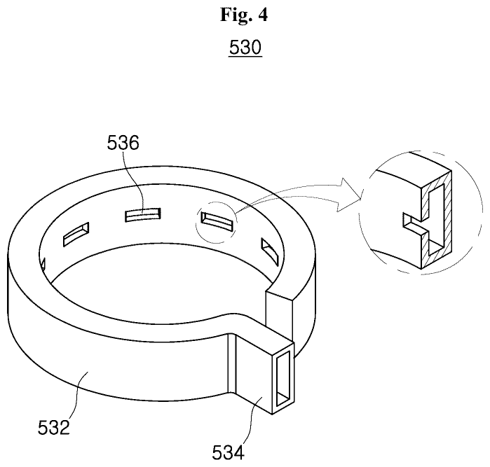

FIG. 4 is a view illustrating the antenna according to an embodiment of the present disclosure. The antenna 530 may transmit microwaves generated from the power source 510 to the substrate W.

Referring to FIG. 4, the antenna 530 according to an embodiment of the present disclosure may include a first part 532 and a second part 534, and the first part 532 and the second part 534 may be formed as an integral part.

The first part 532 may be provided in a doughnut shape, and may be provided such that one portion of the first part 532 is cut. A plurality of output slots 536 may be provided in an inner circumference of the first part 532. The output slot 536 may be provided as a penetration slit that passes through a side surface of the first part 532. Furthermore, optionally, the output slot 536 may be filled with a material that transmits microwaves. The plurality of output slots 536 may be disposed to be spaced apart from each other by a predetermined distance along the inner circumference of the first part 532. The output slot 536 may have a rectangular shape along a diameter direction of the antenna 530, but is not limited thereto. As an example, the plurality of output slots 536 may have predetermined angles.

The second part 534 may extend from the first part 532. As an example, the second part 534 may extend in a horizontal direction from the side surface of the first part 532. The second part 534 may be coupled to the first part 532, and may be connected to the power source 510.

As such, by forming the plurality of output slots 536 along the inner circumference of the antenna 530, microwaves generated from the power source 510 may be directly radiated to the substrate W. A part of the substrate W may be heated as microwaves are directly radiated to the substrate W. As an example, microwaves may be radiated to a boundary surface between a center region W1 and an edge region W2 of the substrate W. Heat is transferred from a heated portion of the substrate W to an unheated portion of the substrate W, thereby rapidly increasing the temperature of the entire substrate W.

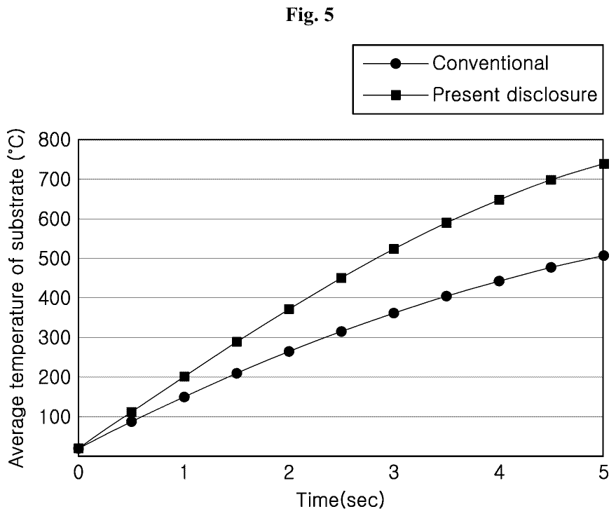

FIG. 5 is a graph showing an average temperature of the substrate according to an embodiment of the present disclosure.

Referring to FIG. 5, an average temperature of a substrate by using an antenna of a conventional microwave unit and an average temperature of a substrate by using the antenna of the microwave unit of the present disclosure are shown in the graph. The average temperature of the substrate is a value secured by adding the temperatures measured multiple times in both the center region and the edge region of the substrate and then dividing by the number of measurements.

By comparing the average temperatures of the substrate at the same time, it can be seen that the average temperature of the substrate W heated by the antenna of the present disclosure is higher than the average temperature of the substrate W heated by the conventional antenna.

Therefore, when the substrate W is heated by using the antenna of the present disclosure, the temperature of the substrate W may be increased more rapidly, and the temperature uniformity of the entire substrate W may be increased.

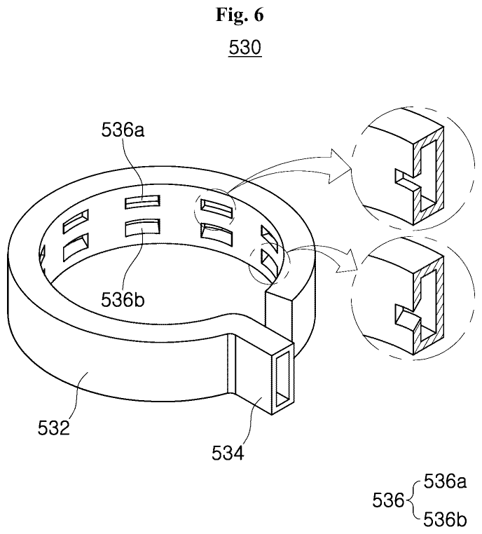

FIG. 6 is a view illustrating the antenna according to another embodiment of the present disclosure.

Referring to FIG. 6, unlike the output slots illustrated in FIG. 4, a plurality of output slots partitioned into layers may be provided. The plurality of output slots 536 in FIG. 6 may include a plurality of output slots 536a and 536b divided into two layers in the vertical direction. The output slot 536a formed on an upper layer along the inner circumference of the antenna 530 may have a first angle, and the output slot 536b formed on a lower layer may have a second angle. The angles of the output slots 536a and 536b according to an embodiment of the present disclosure may be formed with respect to a direction parallel to the surface of the substrate. As an example, the first angle may be 180° and the second angle may be 135°, but the angles are not limited thereto. Therefore, the output slot 536a having the first angle may be configured such that microwaves are directly radiated to the center region W1 of the substrate W, and the output slot 536b having the second angle may be configured such that microwaves are directly radiated to the edge region W2 of the substrate W. Accordingly, since the substrate W is capable of being heated more uniformly, the temperature uniformity of the substrate W may be increased. In addition, in the example described above, the output slots 536 are illustrated such that the output slots 536 have two layers, but there is no limitation.

Referring to FIG. 2 and FIG. 3 again, the microwave unit 500 may further include a microwave unit driving unit 580 for driving the microwave unit 500 in the vertical direction. The microwave unit driving unit 580 may include a microwave unit supporting part 582 and a microwave unit driving part 584.

The microwave unit supporting part 582 may support the microwave unit 580. The microwave unit supporting part 582 may be formed along the circumference of the chamber 100. In order to support the microwave unit 500, the microwave unit supporting part 582 may be provided in the same shape as the microwave unit 500, but the shape of the microwave unit supporting part 582 is not limited thereto. As an example, the microwave unit supporting part 582 may have a doughnut shape 582a and a plate shape 582b, and the doughnut shape 582a and the plate shape 584b may be connected to each other and may be formed as an integral part. The doughnut shape 582a may support the antenna 530 of the microwave unit 500, and the plate shape 582b may support the waveguide 520 and the power source 510 of the microwave unit 500. The microwave unit supporting part 582 may be connected to the microwave unit driving part 584, and may be moved in the vertical direction by the microwave unit driving part 584.

The microwave unit driving part 584 may lift the microwave unit supporting part 582 up and down. Due to the driving of the microwave unit driving part 584, the microwave unit supporting part 582 may be moved in the vertical direction. A hydraulic cylinder, a pneumatic cylinder, and so on may be used in the microwave unit driving part 584, but there is no limitation.

When the microwave unit 500 is driven vertically, the microwave unit 500 may be moved between the substrate support unit 200 and the shower head unit 350, and a position of microwaves radiated to the substrate W may be adjusted by the movement of the microwave unit 500.

The control unit 600 may collectively control the operation of the substrate processing apparatus 10 configured as described above. The control unit 600 may be a computer as an example, and may be provided with a Central Process Unit (CPU), a Random Access Memory (RAM), a Read Only Memory (ROM), an auxiliary memory device, and so on. The CPU is operated on the basis of a program stored in the ROM or the auxiliary memory device or on the basis of a process condition, and may control an overall operation of the substrate processing apparatus 10. In addition, a computer-readable program required for performing the control is capable of being stored in a memory medium. For example, the memory medium may be configured as a flexible disk, a Compact Disc (CD), a CD-ROM, a hard disk, a flash memory, a DVD, or the like. The control unit 600 may be provided inside the substrate processing apparatus 10 or may be provided outside the substrate processing apparatus 10. When the control unit 600 is provided outside the substrate processing apparatus 10, the control unit 600 may control the substrate processing apparatus 10 by a wired communication mechanism or a wireless communication mechanism.

The control unit 600 according to an embodiment of the present disclosure may control the plasma generation unit 300, the gas supply unit 400, and the microwave unit 500. As an example, the control unit 600 may control the gas supply unit 400 and the plasma generation unit 300 such that the gas supply unit 400 supplies a gas to the processing space inside the chamber 100 and the supplied gas is ionized into plasma by the plasma generation unit 300. The control unit 600 may control the gas supply unit 400 such that the gas supply unit 400 is not driven while the microwave unit 500 is driven. In addition, the control unit 600 may control the microwave unit driving unit 580 such that the microwave unit driving unit 580 is moved in the vertical direction.

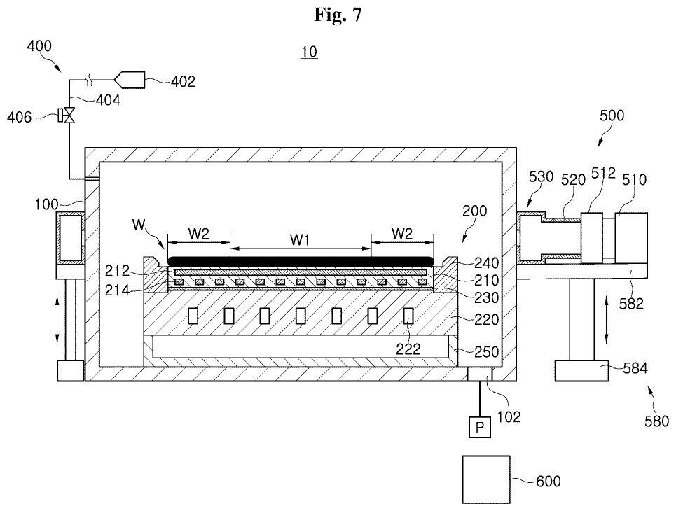

FIG. 7 is a view illustrating the substrate processing apparatus according to another embodiment of the present disclosure.

As illustrated in FIG. 7, unlike the substrate processing apparatus in FIG. 2, a gas supplied to the processing space of the chamber 100 may be ionized into plasma by using the microwave unit 500.

Referring to FIG. 7, the substrate processing apparatus 10 may include the microwave unit 500 so as to generate plasma into the processing space of the chamber 100. The gas supply unit 400 may be directly provided to the processing space through a gas introduction port formed on a side wall of the chamber 100, and a gas supplied to the processing space may be ionized into plasma by the microwave unit 500 formed along the circumference of the chamber 100. By the microwave unit 500 formed along the circumference of the chamber 100, a gas adjacent to the substrate W is ionized into plasma, and the plasma may be applied to the substrate W. Accordingly, the efficiency of applying the plasma to the substrate W may be increased. In addition, by ionizing a gas into plasma at a position adjacent to the substrate W, the uniformity of plasma applied to the substrate W may be increased.

In addition, the microwave unit 500 according to another embodiment of the present disclosure may be driven vertically by the microwave unit driving unit 580. When the microwave unit 500 is driven vertically, the microwave unit 500 may be moved between the substrate supporting unit 200 and the gas supply unit 400. As the microwave unit 500 is driven vertically, a region in which microwaves are supplied to the processing space inside the chamber 100 is capable of being adjusted, so that a region in which the supplied gas is ionized into plasma is also capable of being adjusted.

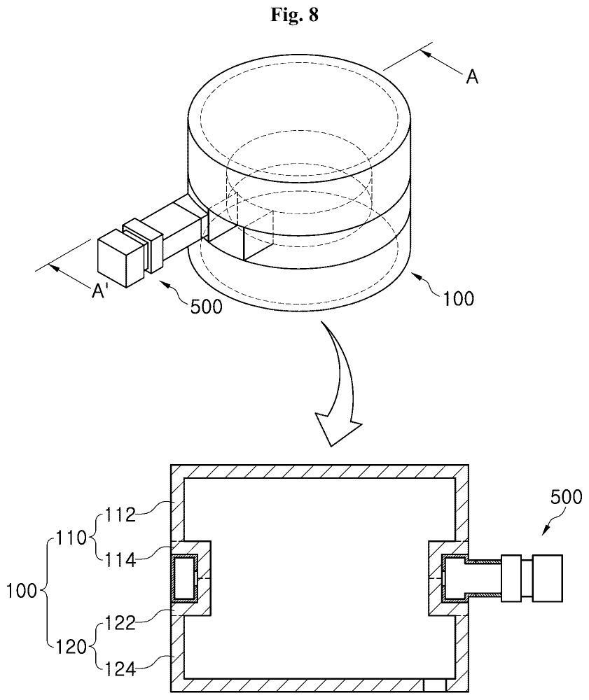

FIG. 8 is a view illustrating the chamber according to another embodiment of the present disclosure.

As illustrated in FIG. 8, unlike the microwave unit 500 formed along the circumference of the chamber 100 in FIG. 3, the microwave unit 500 may be inserted into a portion of the chamber 100.

Referring to FIG. 8, the side wall of the chamber 100 may include a first part 110 and a second part 120, and the first part 110 and the second part 120 may be formed as an integral part. By a combination of the first part 110 and the second part 120, a space may be provided therein.

The first part 110 may include a first upper region 112 having a predetermined diameter and a first lower region 114 having a diameter smaller than the diameter of the first upper region 112.

The second part 120 is disposed below the first part 110, and may have a cylindrical shape with an open upper portion. The second part 120 may include a second lower region 124 having a predetermined diameter and a second upper region 122 having a diameter smaller than the diameter of the second lower region 124. The diameter of the second upper region 122 may be the same as the diameter of the first lower region 114, and the second upper region 122 and the first lower region 114 may be coupled to each other and may have a shape in which a portion of the shape is recessed toward the processing space of the chamber 100.

Therefore, the side wall constituting the chamber 100 may have a region having a portion recessed toward the processing space of the chamber 100, and the microwave unit 500 may be disposed in the recessed region. In this situation, the microwave unit driving unit 580 for driving the microwave unit 500 in the vertical direction may not be formed.

Although the embodiments of the present disclosure have been disclosed for illustrative purposes, those skilled in the art will appreciate that various modifications, additions, and substitutions are possible, without departing from the scope and spirit of the present disclosure. Accordingly, embodiments disclosed in the present disclosure are provided for describing the present disclosure and are not intended to limit the technical ideas of the present disclosure. The technical ideas of the present disclosure are not limited to the embodiments. The scope of the present disclosure should be construed as being covered by the scope of the appended claims, and all technical ideas falling within the scope of the claims should be construed as being included in the scope of the present disclosure.

What is claimed is:

1. A substrate processing apparatus comprising:
a chamber having a processing space therein;
a substrate supporting unit disposed in the processing space and configured to support a substrate; and
a microwave unit for supplying microwaves to the processing space,
wherein the microwave unit is formed along a circumference of the chamber, and is configured to directly radiate microwaves to the processing space of the chamber and to the substrate.

2. The substrate processing apparatus of claim 1, wherein the microwave unit comprises:
a power source for generating the microwaves;
a waveguide for transmitting the microwaves; and
an antenna for transmitting the microwaves, the antenna being formed in a doughnut shape.

3. The substrate processing apparatus of claim 2, wherein a plurality of output slots is formed in an inner circumference of the antenna.

4. The substrate processing apparatus of claim 3, wherein the plurality of output slots is disposed to be spaced apart from each other by a predetermined distance along the inner circumference of the antenna.

5. The substrate processing apparatus of claim 4, wherein the plurality of output slots is disposed as a plurality of layers partitioned in a vertical direction along the inner circumference of the antenna.

6. The substrate processing apparatus of claim 5, wherein the plurality of output slots has an angle of 90° to 180° with respect to a direction parallel to a surface of the substrate.

7. The substrate processing apparatus of claim 1, wherein the chamber is formed of quartz.

8. The substrate processing apparatus of claim 1, wherein a side wall forming the chamber comprises a region recessed toward the processing space from the side wall, and the microwave unit is disposed in the region that is recessed.

9. The substrate processing apparatus of claim 1, further comprising a microwave unit driving unit for driving the microwave unit up and down.

10. A substrate processing apparatus comprising:
a chamber having a processing space therein;
a substrate supporting unit disposed in the processing space and configured to support a substrate;
a gas supply unit for supplying a gas to the processing space;
a plasma generation unit for ionizing the supplied gas into plasma;
a microwave unit for supplying microwaves to the processing space; and
a control unit for controlling the gas supply unit and the plasma generation unit,
wherein the microwave unit is formed along a circumference of the chamber, and is configured to heat the substrate by directly radiating the microwaves to the substrate.

11. The substrate processing apparatus of claim 10, wherein the microwave unit comprises:
a power source for generating the microwaves;
a waveguide for transmitting the microwaves; and
an antenna for transmitting the microwaves, the antenna being formed in a doughnut shape.

12. The substrate processing apparatus of claim 11, wherein a plurality of output slots is formed in an inner circumference of the antenna.

13. The substrate processing apparatus of claim 12, wherein the plurality of output slots is disposed to be spaced apart from each other by a predetermined distance along the inner circumference of the antenna.

14. The substrate processing apparatus of claim 10, further comprising a microwave unit driving unit for driving the microwave unit up and down.

15. A substrate processing apparatus comprising:
a chamber having a processing space therein;
a substrate supporting unit disposed in the processing space and configured to support a substrate;
a gas supply unit for supplying a gas to the processing space;
a microwave unit for supplying microwaves to the processing space; and
a control unit for controlling the gas supply unit and the microwave unit,
wherein the microwave unit is formed along a circumference of the chamber, and is configured to ionize the supplied gas into plasma by directly radiating the microwaves to the processing space of the chamber.

16. The substrate processing apparatus of claim 15, wherein the microwave unit comprises:
a power source for generating the microwaves;
a waveguide for transmitting the microwaves; and
an antenna for transmitting the microwaves, the antenna being formed in a doughnut shape.

17. The substrate processing apparatus of claim 16, wherein a plurality of output slots is formed in an inner circumference of the antenna.

18. The substrate processing apparatus of claim 17, wherein the plurality of output slots is disposed to be spaced apart from each other by a predetermined distance along the inner circumference of the antenna.

19. The substrate processing apparatus of claim 15, further comprising a microwave unit driving unit for driving the microwave unit up and down.

20. The substrate processing apparatus of claim 19, wherein the microwave unit is configured to be driven vertically between the gas supply unit and the substrate supporting unit by the microwave unit driving unit.
